(19) United States
(12) Patent Application Publication
(10) Pub. No.: US 2010/0083900 A1
(43) Pub. Date: Apr. 8, 2010

(54) ATOMIC LAYER DEPOSITION APPARATUS

(75) Inventors: Wen-Ching Sun, Taoyuan County (TW); Yun-Sheng Chung, Hsinchu City (TW); Chung-Wen Lan, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/427,763

(22) Filed: Apr. 22, 2009

(30) Foreign Application Priority Data
Oct. 3, 2008 (TW) 97138273

(51) Int. Cl. C23C 16/00

(52) U.S. Cl. 118/719

(57) ABSTRACT

An atomic layer deposition apparatus is provided. The atomic layer deposition apparatus includes a reaction chamber, a first heater, a second heater, a first gas supply system, a second gas supply system and a vacuum system. The vacuum system is connected to the reaction chamber. The reaction chamber includes a preheating chamber and a plating chamber connected to the preheating chamber. The first heater is for heating the preheating chamber. The first gas supply system is connected to the preheating chamber. The second heater is for heating the plating chamber. The second gas supply system is connected to the plating chamber.

### CROSS-REFERENCE TO RELATED APPLICATION

This application claims the priority benefit of Taiwan application serial no. 97138273, filed Oct. 3, 2008. The entirety of the above-mentioned patent application is hereby incorporated by reference herein and made a part of specification.

### BACKGROUND OF THE INVENTION

1. Field of the Invention

The present invention relates to a semiconductor apparatus, and more particularly to an atomic layer deposition apparatus.

2. Description of Related Art

Solar energy is a renewable energy, which causes no pollution. It has been the focus in the development of environment-friendly energy as an attempt to solve the problems such as pollution and shortage of fossil fuels. Since solar cells can directly convert solar energy into electrical energy, they have become a rather important research topic nowadays.

A passivation layer in a solar cell is the major key to the efficiency of the solar cell. A good passivation layer can be bonded with a dangling bond on a silicon surface or in a defect (e.g., dislocation, chip boundary, or point defect), effectively reducing the recombination rate of electrons and holes on the silicon surface and in the defect, so as to prolong the lifetime of a small number of carriers to enhance the efficiency of the solar cell.

Generally, the passivation layer is manufactured in an atomic layer deposition (ALD) apparatus. However, most current atomic layer deposition apparatuses are mainly single-wafer experimental machines and have poor temperature uniformity. Such atomic layer deposition apparatuses can only grow a single material on the wafer, and therefore not only have a low throughput but the manufactured passivation layer also has dissatisfactory performance.

Accordingly, how to design an atomic layer deposition apparatus which enhances yield and the inactivating effect of the passivation layer so as to improve the efficiency of the solar cell has become one of the issues taken rather seriously by the industry.

### SUMMARY OF THE INVENTION

In view of the foregoing, the present invention provides an atomic layer deposition apparatus, which enhances yield and the inactivating effect of a passivation layer so as to improve the efficiency of a solar cell.

The present invention provides an atomic layer deposition apparatus including a reaction chamber, a first heater, a first gas supply system, a second heater, a second gas supply system and a vacuum system. The vacuum system is connected to the reaction chamber. The reaction chamber includes a preheating chamber and a plating chamber connected to the preheating chamber. The first heater is used for heating the preheating chamber. The first gas supply system is connected to the preheating chamber. The second heater is used for heating the plating chamber. The second gas supply system is connected to the plating chamber.

According to an embodiment of the present invention, the preheating chamber and the plating chamber are separated from each other by a vacuum valve.

According to an embodiment of the present invention, the first heater is disposed on an outer side of the preheating chamber.

According to an embodiment of the present invention, the first heater is disposed on an inner side of the preheating chamber.

According to an embodiment of the present invention, the first heater surrounds an inner wall of the preheating chamber.

According to an embodiment of the present invention, the first gas supply system includes a first gas supply source and a first gas supply pipe. The first gas supply source is connected to the preheating chamber through the first gas supply pipe.

According to an embodiment of the present invention, the first gas supply source includes oxygen or clean dry air.

According to an embodiment of the present invention, the first gas supply system includes a plurality of first pipes extending inside the preheating chamber. Each of the first pipes has a plurality of holes.

According to an embodiment of the present invention, the first pipes surround the inner wall of the preheating chamber.

According to an embodiment of the present invention, the second heater is disposed on an outer side of the plating chamber.

According to an embodiment of the present invention, the second heater is disposed on an inner side of the plating chamber.

According to an embodiment of the present invention, the second heater surrounds an inner wall of the plating chamber.

According to an embodiment of the present invention, the second gas supply system includes a second gas supply source and a second gas supply pipe. The second gas supply source is connected to the plating chamber through the second gas supply pipe.

According to an embodiment of the present invention, the second gas supply source includes precursor materials for performing an atomic layer deposition.

According to an embodiment of the present invention, the second gas supply system includes a plurality of second pipes extending inside the plating chamber. Each of the second pipes has a plurality of holes.

According to an embodiment of the present invention, the second pipes surround the inner wall of the plating chamber.

According to an embodiment of the present invention, the atomic layer deposition apparatus further includes a cooling chamber connected to the plating chamber.

According to an embodiment of the present invention, the cooling chamber and the plating chamber are separated from each other by a vacuum valve.

According to an embodiment of the present invention, the vacuum system includes a vacuum pipe and a vacuum pump. The vacuum pump is connected to the reaction chamber through the vacuum pipe.

According to an embodiment of the present invention, the vacuum system is connected to the preheating chamber and the plating chamber respectively.

According to an embodiment of the present invention, the vacuum system includes a first vacuum system and a second vacuum system. The first vacuum system is connected to the preheating chamber, and the second vacuum system is connected to the plating chamber.

According to an embodiment of the present invention, the vacuum system includes a plurality of pipes extending inside the preheating chamber and the plating chamber.

According to an embodiment of the present invention, the pipes surround the inner walls of the preheating chamber and the plating chamber.

In the present invention, by applying the preheating chamber and the plating chamber, the atomic layer deposition apparatus can solve the problem of poor temperature uniformity in the conventional atomic layer deposition apparatus and manufacture good passivation layers with a satisfactory inactivating effect, so that the yield and performance of the products are enhanced. In addition, the atomic layer deposition apparatus of the present invention makes a plurality of wafers or even a plurality of batches of wafers react at one time, so that the yield is significantly increased, the fabrication cost is saved and the competitiveness is enhanced.

In order to make the aforementioned and other objects, features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of an atomic layer deposition apparatus according to an embodiment of the present invention.

FIG. 2 is a schematic view of an atomic layer deposition apparatus according to another embodiment of the present invention.

FIG. 3 is a partially enlarged schematic view of an inside of a preheating chamber according to an embodiment of the present invention.

FIG. 4 is a schematic view of an atomic layer deposition apparatus according to still another embodiment of the present invention.

### DESCRIPTION OF EMBODIMENTS

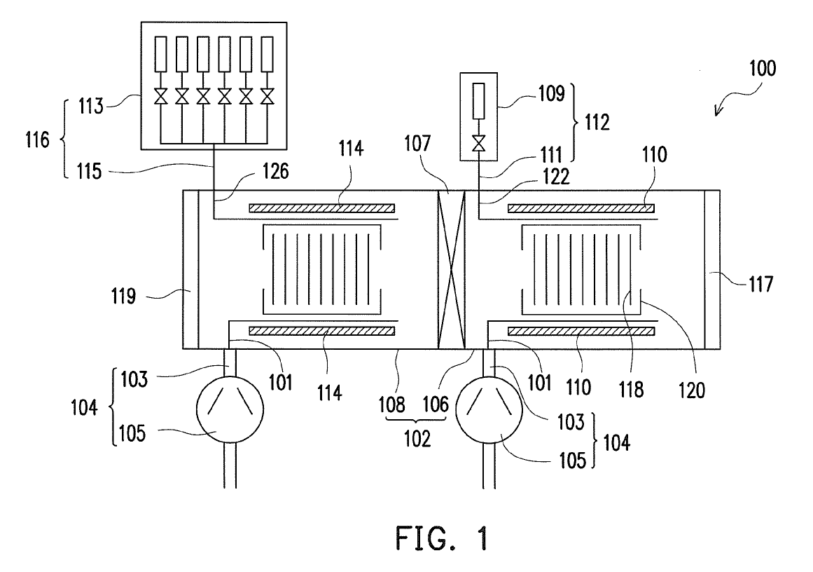

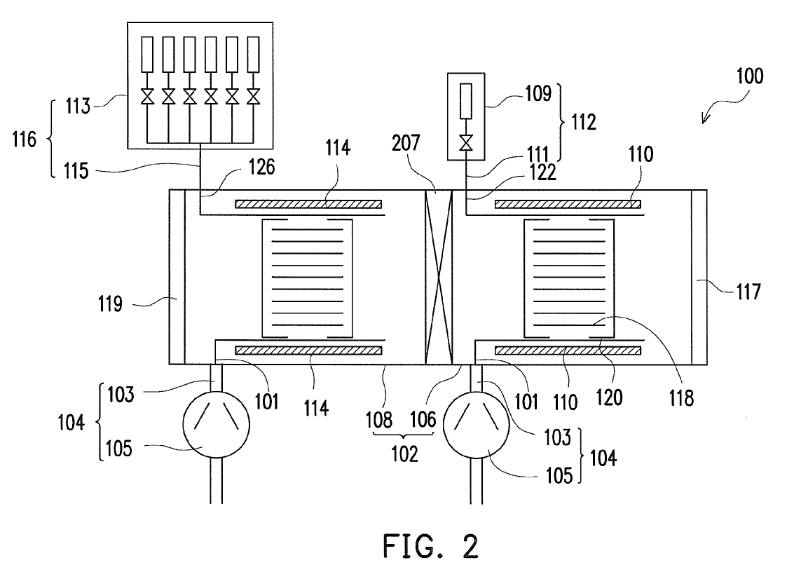

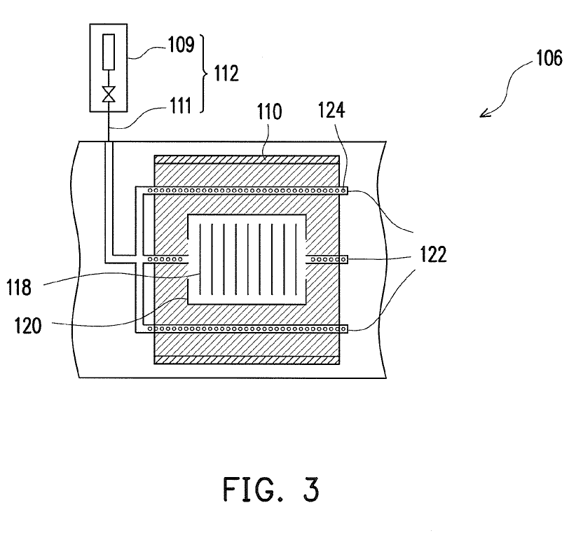

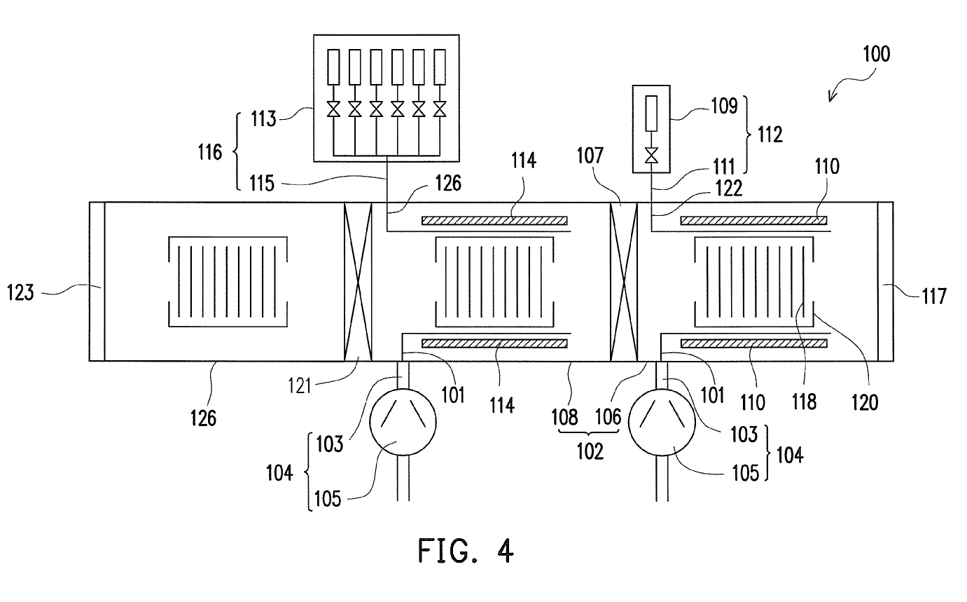

FIG. 1 is a schematic view of an atomic layer deposition apparatus according to an embodiment of the present invention. FIG. 2 is a schematic view of an atomic layer deposition apparatus according to another embodiment of the present invention. FIG. 3 is a partially enlarged schematic view of an inside of a preheating chamber according to an embodiment of the present invention. FIG. 4 is a schematic view of an atomic layer deposition apparatus according to still another embodiment of the present invention.

Referring to FIG. 1, an atomic layer deposition apparatus 100 includes a reaction chamber 102 and a vacuum system 104. The reaction chamber 102 includes a preheating chamber 106 and a plating chamber 108 separated from each other by a vacuum valve 107. The vacuum system 104 is connected to the reaction chamber 102. Specifically, the vacuum system 104 includes a vacuum pipe 103 and a vacuum pump 105. The vacuum pump 105 is connected to the reaction chamber 102 through the vacuum pipe 103. According to an embodiment, the vacuum system 104 is connected to the preheating chamber 106 and the plating chamber 108 respectively, as shown by FIG. 1. According to another embodiment (not shown), the vacuum system 104 includes a first vacuum system and a second vacuum system. The first vacuum system is connected to the preheating chamber 106, and the second vacuum system is connected to the plating chamber 108. Moreover, the vacuum system 104 further includes a plurality of pipes 101 extending inside the preheating chamber 106 and the plating chamber 108.

The atomic layer deposition apparatus 100 further includes a heater 110 and a gas supply system 112. The heater 110 is used for heating the preheating chamber 106. According to an embodiment, the heater 110 is, for example, disposed on an inner side of the preheating chamber 106, as shown by FIG. 1. According to another embodiment (not shown), the heater 110 may also be disposed on an outer side of the preheating chamber 106. Furthermore, the gas supply system 112 is connected to the preheating chamber 106. The gas supply system 112 includes a gas supply source 109 and a gas supply pipe 111. The gas supply source 109 is connected to the preheating chamber 106 through the gas supply pipe 111. Additionally, the gas supply system 112 further includes a plurality of pipes 122 extending inside the preheating chamber 106.

The atomic layer deposition apparatus 100 further includes a heater 114 and a gas supply system 116. The heater 114 is used for heating the plating chamber 108. According to an embodiment, the heater 114 is, for example, disposed on an inner side of the plating chamber 108, as shown by FIG. 1. According to another embodiment (not shown), the heater 114 may also be disposed on an outer side of the plating chamber 108. Furthermore, the gas supply system 116 is connected to the plating chamber 108. The gas supply system 116 includes a gas supply source 113 and a gas supply pipe 115. The gas supply source 113 is connected to the plating chamber 108 through the gas supply pipe 115. Additionally, the gas supply system 116 further includes a plurality of pipes 126 extending inside the plating chamber 108.

The preheating chamber 106 and the plating chamber 108 further include a gate 117 and a gate 119 respectively. A cassette 120 carrying a plurality of wafers 118 is placed inside the reaction chamber 102 through the gate 117 of the preheating chamber 106. After the reaction is completed in the reaction chamber 102, the cassette 120 is removed from the reaction chamber 102 through the gate 119 of the plating chamber 108. According to an embodiment, the wafers 118 are disposed as perpendicular to a bottom surface of the reaction chamber 102 in the cassette 120, as shown by FIG. 1, for example. However, the present invention is not limited to this arrangement. According to another embodiment, the wafers 118 are disposed as parallel to the bottom surface of the reaction chamber 102 in the cassette 120, as shown by FIG. 2.

Next, a detailed description of dispositions inside the preheating chamber 106 and the plating chamber 108 is provided below. The disposition inside the preheating chamber 106 is similar to that inside the plating chamber 108. Hence, the disposition is exemplified by the preheating chamber 106 for explanation as follows. FIG. 3 is a partially enlarged schematic view of an inside of a preheating chamber according to an embodiment of the present invention. To simplify the drawings for the convenience of explanation, only the heater 110 and the inner pipes 122 of the gas supply system 112 are shown in FIG. 3. The disposition of the inner pipes 101 of the vacuum system 104 is similar to that of the inner pipes 122 of the gas supply system 112 and thus not shown in FIG. 3.

Referring to FIG. 3, the cassette 120 carrying the wafers 118 is placed in the preheating chamber 106, and the heater 110 is disposed on the inner side of the preheating chamber 106. Particularly, the heater 110 surrounds an inner wall of the preheating chamber 106. According to an embodiment, the heater 110 is, for example, formed integrally surrounding a top surface, a bottom surface and at least a portion of side surfaces of the cassette 120 as shown by FIG. 3, but the present invention is not limited thereto. People skilled in the art should know that the heater 110 may be in any shape, such as in a strip shape arranged around the cassette 120, as long as the heater 110 can heat the cassette 120 uniformly.

Moreover, the gas supply system 112 further includes the plurality of pipes 122 extending inside the preheating chamber 106. In detail, the pipes 122 surround the inner wall of the preheating chamber 106, and each of the pipes 122 has a plurality of holes 124. The holes 124 are used for distributing the reactive gas evenly in the preheating chamber 106. In more detail, in the gas supply system 112, the gas supply source 109 is connected to the preheating chamber 106 through the gas supply pipe 111, and the reactive gas is then distributed evenly in the preheating chamber 106 through the holes 124 on the pipes 122.

Additionally, the plurality of pipes 101 of the vacuum system 104 extending inside the preheating chamber 106 similarly surround the inner wall of the preheating chamber 106. In other words, the gas may enter and be extracted through a top surface, a bottom surface, and at least a portion of the side surfaces of the preheating chamber 106, such that the reactive gas is heated by the heater 110 and reacts with the wafers 118 through air holes (not shown) of the cassette 120.

The process flow of operating the atomic layer deposition apparatus 100 of the present invention is illustrated in the following. According to an embodiment, wafers 118 are used for manufacturing solar cells, and a photoelectric conversion layer (not shown) has been formed on each of the wafers 118. A material of the photoelectric conversion layer is silicon or silicon alloy, for example. First, a cassette 120 carrying the wafers 118 is placed inside a preheating chamber 106 through a gate 117 of the preheating chamber 106. A reactive gas supplied to the preheating chamber 106 by a gas supply source 109 is oxygen or clean dry air (CDA), for example. Therefore, a first passivation layer (not shown) is formed on the photoelectric conversion layer on each wafer 118. In other words, the first passivation layer is an oxide layer of the photoelectric conversion layer, e.g., silicon oxide layer.

Afterwards, the cassette 120 is placed in a plating chamber 108 through a vacuum valve 107 by a robot arm or a conveyor belt (not shown). Reactive gases supplied to the plating chamber 108 by a gas supply source 113 are precursor materials for performing an atomic layer deposition, for example. Hence, a second passivation layer (not shown) is formed on the first passivation layer on each wafer 118. For example, when a material of the second passivation layer is aluminum oxide, the reactive gases supplied to the plating chamber 108 by the gas supply source 113 are precursor materials of aluminum oxide, e.g., oxygen molecules and aluminum atoms. Thereafter, the cassette 120 is removed from the plating chamber 108 through a gate 119.

Furthermore, the atomic layer deposition apparatus 100 of the present invention may also include a cooling chamber 126. The cooling chamber 126 is connected to the plating chamber 108, as shown by FIG. 4. The cooling chamber 126 and the plating chamber 108 are separated from each other by a vacuum valve 121. After the first passivation layer and the second passivation layer are formed sequentially on each wafer 118 through the preheating chamber 106 and the plating chamber 108, the cassette 120 may optionally be placed inside the cooling chamber 126 by the robot arm or the conveyor belt (not shown) through the vacuum valve 121 for lowering its temperature uniformly. Afterwards, the cassette 120 is removed from the cooling chamber 126 through a gate 123.

In summary, the atomic layer deposition apparatus of the present invention forms the first passivation layer and the second passivation layer sequentially on the wafer through the preheating chamber and the plating chamber. Then, the wafer may also lower its temperature uniformly through the cooling chamber optionally. Therefore, the structure of double passivation layers in the solar cell manufactured by the atomic layer deposition apparatus of the present invention effectively increases the surface inactivating effect and the lifetime of carriers, so that the efficiency of the solar cell is enhanced. In other words, the problem of poor temperature uniformity in the conventional atomic layer deposition apparatus is mitigated by the preheating chamber and the cooling chamber of the present invention, so that the yield and performance of the products are enhanced.

Additionally, the atomic layer deposition apparatus of the present invention makes a plurality of wafers or even a plurality of batches of wafers react at one time. That is, the process flow of the plurality of batches of wafers carried out in the preheating chamber, the plating chamber and the cooling chamber is continuous. For example, when one of the batches of wafers are reacted in the plating chamber, another batch of wafers stand by to be processed in the preheating chamber. Thus, the bottleneck faced by the process of the atomic layer deposition apparatus is overcome and the yield is significantly increased. The continuous process flow is both cost-effective and competitive.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An atomic layer deposition apparatus, comprising:
a reaction chamber, comprising:
a preheating chamber; and
a plating chamber, connected to the preheating chamber;
a first heater, used for heating the preheating chamber;
a first gas supply system, connected to the preheating chamber;
a second heater, used for heating the plating chamber;
a second gas supply system, connected to the plating chamber; and
a vacuum system, connected to the reaction chamber.

2. The atomic layer deposition apparatus of claim 1, wherein the preheating chamber and the plating chamber are separated from each other by a vacuum valve.

3. The atomic layer deposition apparatus of claim 1, wherein the first heater is disposed on an outer side of the preheating chamber.

4. The atomic layer deposition apparatus of claim 1, wherein the first heater is disposed on an inner side of the preheating chamber.

5. The atomic layer deposition apparatus of claim 4, wherein the first heater surrounds an inner wall of the preheating chamber.

6. The atomic layer deposition apparatus of claim 1, wherein the first gas supply system comprises a first gas supply source and a first gas supply pipe, and the first gas supply source is connected to the preheating chamber through the first gas supply pipe.

7. The atomic layer deposition apparatus of claim 6, wherein the first gas supply source comprises oxygen or clean dry air.

8. The atomic layer deposition apparatus of claim 1, wherein the first gas supply system comprises a plurality of first pipes extending inside the preheating chamber, and each of the first pipes has a plurality of holes.

9. The atomic layer deposition apparatus of claim 8, wherein the first pipes surround an inner wall of the preheating chamber.

10. The atomic layer deposition apparatus of claim 1, wherein the second heater is disposed on an outer side of the plating chamber.

11. The atomic layer deposition apparatus of claim 1, wherein the second heater is disposed on an inner side of the plating chamber.

12. The atomic layer deposition apparatus of claim 11, wherein the second heater surrounds an inner wall of the plating chamber.

13. The atomic layer deposition apparatus of claim 1, wherein the second gas supply system comprises a second gas supply source and a second gas supply pipe, and the second gas supply source is connected to the plating chamber through the second gas supply pipe.

14. The atomic layer deposition apparatus of claim 13, wherein the second gas supply source comprises precursor materials for performing an atomic layer deposition.

15. The atomic layer deposition apparatus of claim 1, wherein the second gas supply system comprises a plurality of second pipes extending inside the plating chamber, and each of the second pipes has a plurality of holes.

16. The atomic layer deposition apparatus of claim 15, wherein the second pipes surround an inner wall of the plating chamber.

17. The atomic layer deposition apparatus of claim 1, further comprising a cooling chamber connected to the plating chamber.

18. The atomic layer deposition apparatus of claim 17, wherein the cooling chamber and the plating chamber are separated from each other by a vacuum valve.

19. The atomic layer deposition apparatus of claim 1, wherein the vacuum system comprises a vacuum pipe and a vacuum pump, and the vacuum pump is connected to the reaction chamber through the vacuum pipe.

20. The atomic layer deposition apparatus of claim 1, wherein the vacuum system is connected to the preheating chamber and the plating chamber respectively.

21. The atomic layer deposition apparatus of claim 1, wherein the vacuum system comprises a first vacuum system and a second vacuum system, the first vacuum system is connected to the preheating chamber, and the second vacuum system is connected to the plating chamber.

22. The atomic layer deposition apparatus of claim 1, wherein the vacuum system comprises a plurality of pipes extending inside the preheating chamber and the plating chamber.

23. The atomic layer deposition apparatus of claim 22, wherein the pipes surround inner walls of the preheating chamber and the plating chamber.
